(19) United States
(12) Patent Application Publication
(10) Pub. No.: US 2026/0223569 A1
(43) Pub. Date: Jul. 30, 2026

(54) LIGHT EMITTING DISPLAY DEVICE

(71) Applicant: LG Display Co., Ltd., Seoul (KR)

(72) Inventors: Gwi Jeong CHO, Paju-si (KR); Jin Tae KIM, Paju-si (KR); Ji Hyang JANG, Paju-si (KR)

(73) Assignee: LG Display Co., Ltd., Seoul (KR)

(21) Appl. No.: 19/441,589

(22) Filed: Jan. 6, 2026

(30) Foreign Application Priority Data
Jan. 24, 2025 (KR) 10-2025-0011986

(51) Int. Cl. H10K 59/80; H10K 59/35

(52) U.S. Cl. CPC H10K 59/80517; H10K 59/353

(57) ABSTRACT

Disclosed is a light emitting display device including a first anode at a red subpixel, a second anode at a white subpixel, a third anode at a blue subpixel, and a fourth anode at a green subpixel, an intermediate layer on the first anode, the second anode, the third anode, and the fourth anode, the intermediate layer comprising four or more stacks and a charge generation layer between the stacks and a cathode on the intermediate layer. Each of the first anode and the second anode may have a lower refractive index than each of the third anode and the fourth anode for light of the same wavelength.

### CROSS-REFERENCE TO RELATED APPLICATION(S)

This application claims the benefit of Korean Patent Application No. 10-2025-0011986, filed on Jan. 24, 2025, which is hereby incorporated by reference as if fully set forth herein.

### BACKGROUND

### Technical Field

The present disclosure relates to a light emitting display device.

### Description of the Related Art

In recent years, a self-light emitting display device has been considered as a competitive application in order to achieve reduction in device size and vivid color display without necessity of a separate light source. Based on an internal light emitting material, the self-light emitting display device may be classified as an organic light emitting display device or an inorganic light emitting display device.

Meanwhile, the self-light emitting display device includes a plurality of subpixels, wherein each subpixel is provided with a light emitting device without a separate light source in order to emit light outside.

In addition, with high resolution and high integration of the display device, a tandem structure comprising a plurality of common layers and a plurality of light emitting layers over a plurality of subpixels without requiring a fine metal mask has been considered. Thus, research for the tandem structure has been conducted.

### BRIEF SUMMARY

Embodiments of the present disclosure provide a light emitting display device including a light emitting device with improved luminous efficacy.

Embodiments of the present disclosure provide a light emitting display device having a tandem structure capable of preventing color deviation characteristics due to changes in the viewing angle, thereby improving image quality.

Embodiments of the present disclosure provide a light emitting display device configured such that each of subpixels that emit different colors has an optical structure of a light emitting device corresponding to a specific emission color.

A light emitting display device according to an embodiment of the present disclosure includes a first anode at a red subpixel, a second anode at a white subpixel, a third anode at a blue subpixel, and a fourth anode at a green subpixel, an intermediate layer on the first anode, the second anode, the third anode, and the fourth anode, the intermediate layer comprising four or more stacks and a charge generation layer between the stacks and a cathode on the intermediate layer. Each of the first anode and the second anode may have a lower refractive index than each of the third anode and the fourth anode for light of the same wavelength.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing a light emitting display device according to an embodiment of the present disclosure;

FIG. 2 is a plan view of a unit pixel of the light emitting display device according to the embodiment of the present disclosure;

FIG. 3 is a sectional view taken along line I-I′ in FIG. 2;

FIG. 4 is a sectional view showing an example of a light emitting device of FIG. 3;

FIG. 5 is a graph showing the subpixel-specific anode thickness of the light emitting device of FIG. 4 and the wavelength-specific refractive index thereof;

FIG. 6 is a contour map of a white subpixel and a red subpixel of the light emitting display device according to the embodiment of the present disclosure;

FIG. 7 is a contour map of a blue subpixel and a green subpixel of the light emitting display device according to the embodiment of the present disclosure; and

FIG. 8 is a view showing the color viewing angle characteristics of the blue and green subpixels and the white and red subpixels for comparison.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly) is used. It will be understood that when an element or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped.” For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, a hole transport layer and an electron transport layer.

Hereinafter, preferred embodiments of the present disclosure will be described with reference to the accompanying drawings.

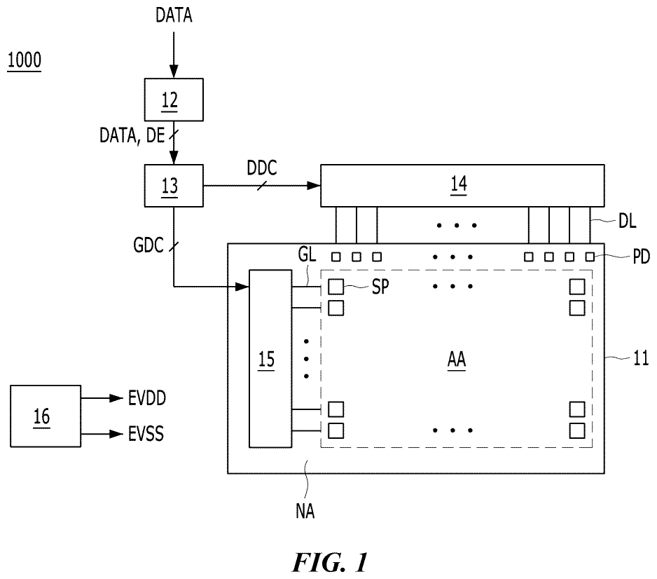

FIG. 1 is a block diagram schematically showing a light emitting display device according to an embodiment of the present disclosure.

As shown in FIG. 1, the light emitting display device 1000 according to the embodiment of the present disclosure may include a display panel 11, an image processing unit 12, a timing controller 13, a data driving unit 14, a scan driving unit 15, and a power supply unit 16.

The display panel 11 may display an image in response to a data signal DATA supplied from the data driving unit 14, a scan signal supplied from the scan driving unit 15, and power supplied from the power supply unit 16.

The display panel 11 may include subpixels SP disposed at intersections of a plurality of gate lines GL and a plurality of data lines DL. The structure of the subpixels SP may vary depending on the type of the light emitting display device 1000.

For example, the subpixels SP may emit light in a top emission, bottom emission, or dual emission manner depending on the structure thereof. A subpixel SP is a unit that can emit a specific color with or without a specific color filter. For example, the subpixels SP may include a red subpixel, a green subpixel, and a blue subpixel. Alternatively, the subpixels SP may include a red subpixel, a blue subpixel, a white subpixel, and a green subpixel. The subpixels SP may have one or more different emission areas based on their emission characteristics. For example, a blue subpixel and subpixels emitting different colors may have different emission areas.

One or more subpixels SP may constitute a unit pixel. For example, a unit pixel may include red, green, and blue subpixels, wherein the red, green, and blue subpixels may be repeatedly disposed. Alternatively, a unit pixel may include red, green, blue, and white subpixels, wherein the red, green, blue, and white subpixels may be repeatedly disposed or the red, green, blue, and white subpixels may be disposed in a Quad type. In the embodiment of the present disclosure, the color type, placement type, placement order, etc., of the subpixels may vary depending on the light emitting characteristics, the lifespan of the device, the specifications of the display device, etc., but the present disclosure is not limited thereto.

The display panel 11 may be divided into an active area AA (in a dotted area) in which the subpixels SP are disposed to display an image and a non-active area NA around the active area AA. The scan driving unit 15 may be mounted at the non-active area NA of the display panel 11. Further, the non-active area NA may include a pad unit PAD including a pad electrode PD.

Here, the active area AA may also be referred to as an active area and the non-active area NA may also be referred to as a non-active area.

The image processing unit 12 may output a data signal DATA supplied from the outside and a data enable signal DE. The image processing unit 12 may output one or more of a vertical synchronization signal, a horizontal synchronization signal, and a clock signal in addition to the data enable signal DE, but a description of these signals will be omitted for convenience.

The timing controller 13 may receive a driving signal and a data signal DATA from the image processing unit 12. The driving signal may include a data enable signal DE. Alternatively, the driving signal may include a vertical synchronization signal, a horizontal synchronization signal, and a clock signal. The timing controller 13 may output a data timing control signal DDC for controlling the operation timing of the data driving unit 14 and a gate timing control signal GDC for controlling the operation timing of the scan driving unit 15 based on the driving signal.

The data driving unit 14 may sample and latch the data signal DATA supplied from the timing controller 13 in response to the data timing control signal DDC supplied from the timing controller 13, convert the same into a gamma reference voltage, and output the same.

The data driving unit 14 may output the data signal DATA through the data lines DL. The data driving unit 14 may be implemented in the form of an integrated circuit (IC). For example, the data driving unit 14 may be electrically connected to the pad electrode PD disposed at the non-active area NA of the display panel 11 via a flexible circuit film (not shown).

The scan driving unit 15 may output a scan signal in response to a gate timing control signal GDC supplied from the timing controller 13. The scan driving unit 15 may output the scan signal via the gate lines GL. The scan driving unit 15 may be implemented in the form of an integrated circuit (IC) or may be implemented as a gate in panel GIP on the display panel 11.

The power supply unit 16 may output a high potential voltage and a low potential voltage to drive the display panel 11. The power supply unit 16 may supply the high potential voltage to the display panel 11 via a first power line EVDD (driving power line or pixel power line), and may supply the low potential voltage to the display panel 11 via a second power line EVSS (auxiliary power line or common power line).

The display panel 11 is divided into an active area AA and a non-active area NA, and may include a plurality of subpixels SP defined by gate lines GL and data lines DL that intersect and form a matrix at the active area AA.

The subpixels SP may include subpixels emitting at least two of red light, green light, blue light, yellow light, magenta light, and cyan light. Further, each of the plurality of subpixels SP may emit a specific color with or without specific color filters. However, the present disclosure is not necessarily limited thereto, and the color type, placement type, placement order, etc., of the subpixels SP may vary depending on the light emitting characteristics, the lifespan of the device, the specifications of the display device, etc.

Each of the subpixels SP may include a light emitting portion and a non-light emitting portion surrounding the light emitting portion.

Hereinafter, a light emitting display device having light emitting portions REM, GEM, BEM, and WEM emitting colors corresponding to a red subpixel RSP, a green subpixel GSP, a blue subpixel BSP, and a white subpixel WSP according to an embodiment of the present disclosure will be described with reference to the drawings.

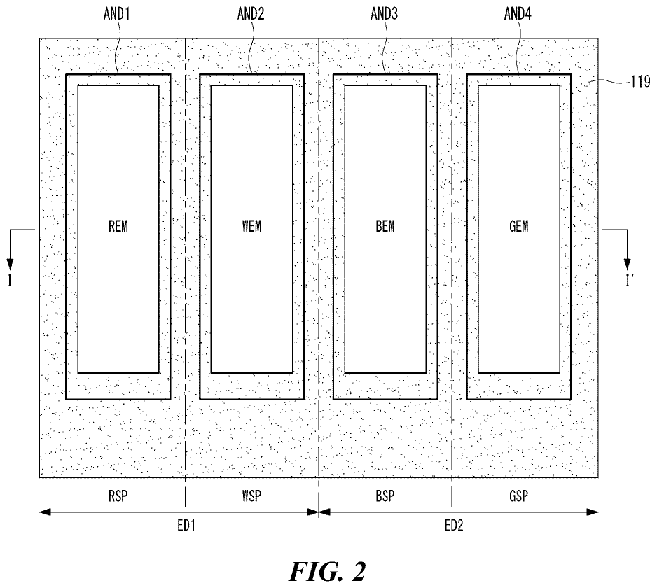

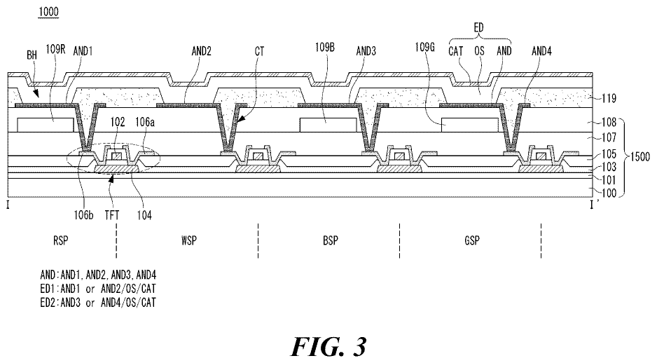

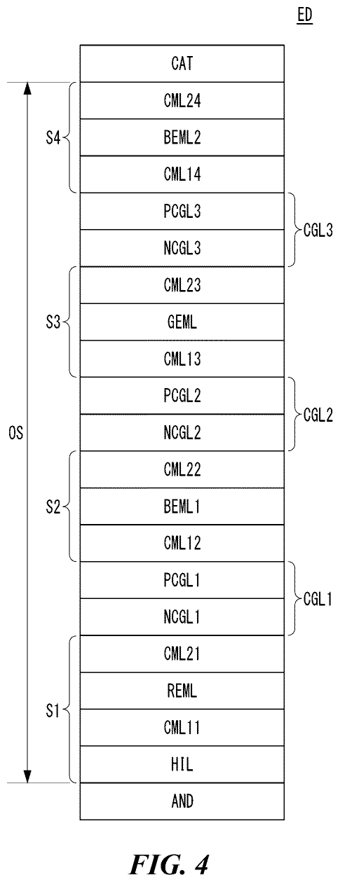

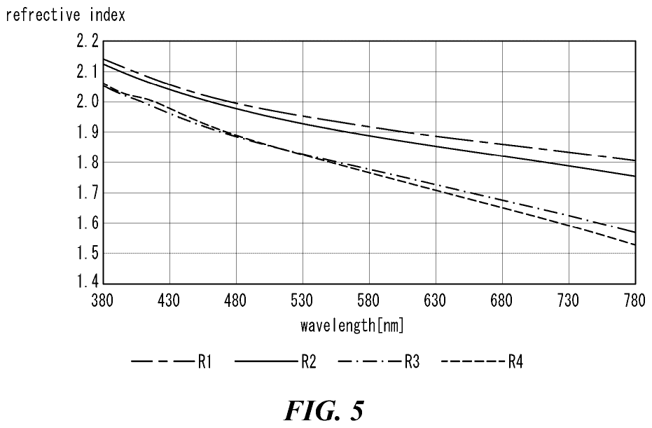

FIG. 2 is a plan view of a unit pixel of the light emitting display device according to the embodiment of the present disclosure, and FIG. 3 is a sectional view taken along line I-I′ in FIG. 2. FIG. 4 is a sectional view showing an example of a light emitting device of FIG. 3. FIG. 5 is a graph showing the subpixel-specific anode thickness of the light emitting device of FIG. 4 and the wavelength-specific refractive index thereof.

A red subpixel RSP, a white subpixel WSP, a blue subpixel BSP, and a green subpixel GSP described herein refer to a plurality of partitioned areas disposed in an active area AA on a substrate 100. FIG. 2 shows a unit pixel including red, white, blue, and green subpixel RSP, WSP, BSP, and GSP.

The substrate 100 may include at least one of a glass substrate, a plastic film, and a metal plate having certain supporting force. The substrate 100 may be made of a flexible material. For example, if the substrate 100 has a plurality of layers, the substrate 100 may have a structure in which a first organic layer, an inorganic insulating layer, and a second organic layer are stacked. The outermost first organic layer may prevent the introduction of external impurities. The second organic layer may enable surface planarization of a formation surface of an inner array structure and prevent charge transfer or impurity transfer from the outside to the inside. The inorganic insulating layer provided between the first and second organic layers may prevent moisture permeation diffusion between the first and second organic layers and the transfer of conductive impurities to the second organic layer.

The red subpixel RSP, the white subpixel WSP, the blue subpixel BSP, and the green subpixel GSP include a red light emitting portion REM, a white light emitting portion WEM, a blue light emitting portion BEM, and a green light emitting portion GEM, respectively, and a non-light emitting portion is provided around each of the light emitting portions REM, WEM, BEM, and GEM.

The non-light emitting portion may be an area where banks 119 defining the light emitting portions REM, WEM, BEM, and GEM of the subpixels are disposed. The banks 119 disposed in the non-light emitting portions between adjacent light emitting portions are connected to each other.

In the light emitting display device according to the embodiments of the present disclosure, each of the red subpixel RSP, the white subpixel WSP, the blue subpixel BSP, and the green subpixel GSP is provided with a light emitting device ED. The light emitting device ED includes an anode AND, an intermediate layer OS, and a cathode CAT. The cathode CAT includes a plurality of light emitting stacks and a charge generation layer between the light emitting stacks. At the red subpixel RSP, the white subpixel WSP, the blue subpixel BSP, and the green subpixel GSP, at least the light emitting device ED has a common intermediate layer OS and a cathode CAT. That is, the red subpixel RSP, the white subpixel WSP, the blue subpixel BSP, and the green subpixel GSP include a plurality of light emitting stacks of the intermediate layer OS and a charge generation layer and are disposed in the same stack structure.

When the intermediate layer OS includes a common stack structure over the plurality of subpixels, the yield is improved compared to a structure in which a plurality of deposition masks is required for separate patterning for each subpixel.

In addition, the luminance may be enhanced by stacking a plurality of light emitting stacks.

However, in a structure where a plurality of light emitting stacks is commonly provided for a plurality of subpixels, the increase in driving voltage due to stacking of the plurality of light emitting stacks and changes in viewing angle when observed at a specific angle from the front may cause noticeable color shifts.

In the light emitting display device according to the present disclosure, it is possible to reduce the driving voltage and to improve color viewing angle characteristics by changing the optical and electrical properties of the anode for each subpixel that ultimately displays different colors from the light emitting device.

As shown in FIGS. 2 and 3, in the display device according to the embodiment of the present disclosure, the red subpixel RSP and the white subpixel WSP have first and second anodes AND1 and AND2 with first characteristics, and the blue subpixel BSP and the green subpixel GSP have third and fourth anodes AND3 and AND4 with second characteristics.

The feature distinguishing the first and second characteristics may be at least one of the refractive index and the resistance.

Each of the red subpixel RSP and the white subpixel WSP including the first and second anodes AND1 and AND2 having the first characteristics includes a first light emitting device ED1, and each of the blue subpixel BSP and the white subpixel GSP including the third and fourth anodes AND3 and AND4 having the second characteristics includes a second light emitting device ED2.

The first and second light emitting devices ED1 and ED2 commonly include an intermediate layer OS and a cathode CAT but exhibit optically different effects due to differences in anode materials. Referring FIG. 4, the intermediate layer OS comprises a first light emitting stack S1 comprising a red light emitting layer REML, a first charge generation layer CGL1, a second light emitting stack S2 comprising a first blue light emitting layer BEML1, a second charge generation layer CGL2, a third light emitting stack S3 comprising a green light emitting layer GEML, a third charge generation layer CGL3 and a fourth light emitting stack S4 comprising a second blue light emitting layer BEML2.

The first to fourth anodes AND1, AND2, AND3, and AND4 of the subpixel RSP, WSP, BSP, and GSP of the present disclosure include a transparent metal oxide as an anode material, but the optical properties may be varied by changing the layer formation conditions during deposition.

TABLE 1

| | | Anode material | Anode material |
|---|---|---|---|
| | | with first | with second |
| | Category | characteristics | characteristics |
| Layer formation | Speed | slow | fast |
| conditions | Power | high | low |
| Physical | Surface | 50 | 146 |
| properties | resistance | | |
| | (Ω/□) | | |
| | Refractive | 1.92 | 2.01 |
| | Index @ 454 | | |
| | nm | | |
| | Refractive | 1.83 | 1.93 |
| | Index @ 530 | | |
| | nm | | |
| | Refractive | 1.73 | 1.85 |
| | Index @ 630 | | |
| | nm | | |
| Light emitting | Peak driving | Vp-0.3 V | Vp |
| device | voltage | | |
| characteristics | | | |

| | | |
|---|---|---|
| Applied subpixels | WSP, RSP | BSP, GSP |

Table 1 shows the layer formation conditions and physical properties of the anode material of the first characteristics included in the first and second anodes AND1 and AND2 and the anode material of the second characteristics included in the third and fourth anodes AND3 and AND4, and shows the peak driving voltage when each anode material is applied as an anode of the light emitting device.

The anode material of the first characteristics is layer-formed at a lower speed and higher power than the anode material of the second characteristics, and depending on the layer formation conditions, the anode material of the first characteristics has a smaller surface resistance than the anode material of the second characteristics at the same thickness, and the anode material of the second characteristics has a lower refractive index in the same wavelength range than the anode material of the first characteristics at the same thickness.

The first and second anodes AND1 and AND2 of the red subpixel RSP and the white subpixel WSP may have smaller surface resistance and refractive index than the third and fourth anodes AND3 and AND4 of the blue subpixel BSP and the green subpixel GSP. Furthermore, due to the property differences between the first and second characteristics, the peak driving voltage Vpeak of the light emitting device ED2 of each of the red subpixel RSP and the white subpixel WSP may be lower by 0.3V than the peak driving voltage of the light emitting device ED2 of each of the blue subpixel BSP and green subpixel GSP.

Table 1 shows an example of the anode material with the first characteristics applied to the red and white subpixels RSP and WSP and the anode material with the second characteristics applied to the blue and green subpixels BSP and GSP.

The example shown in Table 1 is an example. Referring to FIG. 5, the first anode AND1 and the second anode AND2 having the first characteristics may have a refractive index of 1.65 to 1.78 for a red wavelength, a refractive index of 1.79 to 1.85 for a green wavelength, and a refractive index of 1.90 to 1.97 for a blue wavelength.

As shown in Table 1 and FIG. 5, the refractive index difference between the third anode AND3 and fourth anode AND4 having the second characteristics and the first and second anodes AND1 and AND2 may decrease as the wavelength of light becomes shorter.

FIG. 5 shows the refractive index of each of the anode materials R1, R2, R3, and R4 having different surface resistances as a function of wavelength.

In the anode materials, the surface resistance decreases gradually from R1 to R4. The lower the surface resistance at the same wavelength, the lower the refractive index.

The anode materials R3 and R4 of the first characteristics with relatively low refractive indices may be used as anode materials for the white subpixel and the red subpixel. The anode materials R1 and R2 of the second characteristics with relatively high refractive indices may be used as anode materials for the blue subpixel and the green subpixel.

In the experiment shown in Table 1, the material R2 was used as the third and fourth anodes for the blue and green subpixels, and the material R3 was used as the first and second anodes for the white and red subpixels.

In Table 1, the anode material with the same first characteristics was applied to the first anode AND1 of the red subpixel RSP and the second anode AND2 of the white subpixel WSP, and the anode material with the same second characteristics was applied to the third anode AND3 of the blue subpixel BSP and the fourth anode AND4 of the green subpixel GSP.

However, the present disclosure is not limited thereto.

The first anode AND1 and the second anode AND2 may have a lower refractive index for light of the same wavelength than the third anode AND3 and the fourth anode AND4.

The first anode AND1 and the second anode AND2 may have a lower surface resistance than the third anode AND3 and the fourth anode AND4.

The first anode AND1, the second anode AND2, the third anode AND3, and the fourth anode AND4 may have the same thickness. The first to fourth anodes AND1, AND2, AND3, and AND4 may have differences in the layer formation conditions but the same thickness so as not to be affected by electrical characteristics other than surface resistance and refractive index.

Each of the first anode AND1, the second anode AND2, the third anode AND3, and the fourth anode AND4 may have a thickness of 450 Å to 650 Å. This thickness is significantly less than that of a 3-stack light emitting device, minimizing the thickness of the intermediate layer between the first to fourth anodes AND1, AND2, AND3, and AND4 and the cathode CAT in the light emitting device, suppressing an increase in driving voltage in a multi-stack light emitting device, and optimizing efficiency.

The first anode AND1 and the second anode AND2 may have the same refractive index, and the third anode AND3 and the fourth anode AND4 may have the same refractive index.

The first anode AND1 and the second anode AND2 may have the same first surface resistance, and the third anode AND3 and the fourth anode AND4 may have a second surface resistance greater than the first surface resistance.

Each of the first anode AND1, the second anode AND2, the third anode AND3, and the fourth anode AND4 may include any one of indium-tin oxide (ITO) and indium-zinc oxide (IZO).

Each of the first anode AND1, the second anode AND2, the third anode AND3, and the fourth anode AND4 includes a transparent metal oxide. The oxygen content of each of the first anode AND1 and the second anode AND2 may be less than the oxygen content of each of the third anode AND3 and the fourth anode AND4, whereby the resistance of the material forming the first and second anodes AND1 and AND2 may be lower than that of the material forming the third and fourth anodes AND3 and AND4.

Each of the first anode AND1, the second anode AND2, the third anode AND3, and the fourth anode AND4 includes a transparent metal oxide. Here, the crystal size in the transparent metal oxide of each of the first anode AND1 and the second anode AND2 may be greater than the crystal size in the transparent metal oxide of each of the third anode AND3 and the fourth anode AND4. In this case, the first and second anodes AND1 and AND2 may have lower resistance and higher conductivity than the third and fourth anodes AND3 and AND4.

Table 1 shows the results of experiments conducted using indium tin oxide (ITO) as each anode material with different layer formation conditions to achieve different physical properties. In the experiments, the thicknesses of the first to fourth anodes AND1, AND2, AND3, and AND4 was maintained within a range of 450 Å to 650 Å, with all anodes having the same thickness. The thicknesses of the first to fourth anodes AND1, AND2, AND3, and AND4 were determined in consideration of the optimization of the efficiency of the light emitting device and the minimization of the thickness of the intermediate layer in the light emitting device as the number of light emitting stacks in the light emitting device increases.

Generally, increasing the thickness of the anode reduces the surface resistance. In the light emitting display device according to the embodiment of the present disclosure, a 4-or-more-stack light emitting device has first to fourth anodes AND1, AND2, AND3, and AND4 having a thickness less than that of an anode of a 3-stack light emitting device, and the refractive index and surface resistance at the red and white subpixels RSP and BSP are reduced by changing the layer formation conditions, thereby achieving optimum efficiency.

In the light emitting display device according to the embodiment of the present disclosure, the thickness of each of the first to fourth anodes AND1, AND2, AND3, and AND4 is 450 Å to 650 Å.

In the experiments, the light emitting device was configured such that four light emitting stacks and three charge generation layers were provided in the intermediate layer OS, as shown in FIG. 4.

The light emitting display device according to the present disclosure includes four or more light emitting stacks to improve luminance. The light emitting display device according to the present disclosure is proposed to prevent luminance degradation and color deviation, which are vulnerable to changes in the viewing angle, as the number of light emitting stacks increases in order to improve luminance. In the light emitting display device according to the present disclosure, first and second anodes AND1 and AND2 having first characteristics of a small refractive index may be provided to the white subpixel and the red subpixel, which have relatively larger efficiency differences depending on the viewing angle change, whereby it is possible to improve the visual perception characteristics due to the viewing angle change.

Here, the first to fourth anodes AND1, AND2, AND3, and AND4 may have different layer formation conditions but the same thickness. The first and second anodes AND1 and AND2 and the third and fourth anodes AND3 and AND4 differ in at least one of refractive index or surface resistance due to layer formation conditions, rather than thickness.

The red subpixel RSP and the white subpixel WSP including the first and second anodes AND1 and AND2 with low surface resistance may have an effect of reducing the driving voltage of the light emitting device by the first and second anodes AND1 and AND2 with low surface resistance meeting the intermediate layer.

In addition, the red subpixel RSP and the white subpixel WSP having the first and second anodes AND1 and AND2 having a refractive index less than that of the third and fourth anodes AND3 and AND4 for light of the same wavelength band have small color coordinate change depending on viewing angle change when the light emitting display device is observed while the viewing angle changes from the front, whereby it is possible to reduce color deviation due to viewing angle change and to improve the image quality of the light emitting display device.

In the light emitting display device according to the present disclosure, characteristic differences may be imparted to the first and second anodes AND1 and AND2 and the third and fourth anodes AND3 and AND4 such that the refractive index, which is an optical constant, is different at the red subpixel RSP, the white subpixel WSP, the blue subpixel BSP, and the green subpixels GSP, thereby maximizing the efficiency of the anode material at each subpixel, reducing changes in the viewing angle-dependent visual perception characteristics of the light emitting device ED, and improving the image quality of the light emitting display device.

Meanwhile, in the light emitting display device according to the embodiment of the present disclosure, as shown in FIG. 2, in a plan view, the red subpixel RSP and the white subpixel WSP may be disposed adjacent to each other without any gap therebetween. As shown in FIG. 2, in a plan view, the blue subpixel BSP and the green subpixel GSP may be disposed adjacent to each other without any gap therebetween. This facilitates implementation of the light emitting device by disposing subpixels with the same characteristics adjacent to each other and providing blocks with anode materials having different layer formation conditions, thereby enabling application of the same deposition process to each block.

The bank 119 exposes the light emitting portions REM, WEM, BEM, and GEM of the anode AND, and is disposed in the non-light emitting portion. The bank 119 is disposed while covering the edge of each of the anodes AND (AND1, AND2, AND3, and AND4). The bank 119 is open to the light emitting portions REM, WEM, BEM, and GEM, and the anodes AND (AND1, AND2, AND3, and AND4) may be exposed in the open area of the bank 119.

The bank 119 may be made of a transparent or opaque organic material. When the bank 119 includes an opaque organic material, the bank 119 may include a shielding organic material that absorbs or shields at least part of the visible spectrum. The shielding organic material is a material that absorbs light, and includes an organic material that absorbs at least light in the visible spectrum. The bank 119 may include a material such as carbon black or a colored pigment. The bank 119 may also include a stack of a shielding organic material layer and a transmitting organic material layer, or may have a single transmitting organic material layer.

The light emitting display device 1000 may have a circuit configuration including a plurality of transistors TFT and one or more storage capacitors at each of the subpixels RSP, WSP, BSP, and GSP on the substrate 100, and may be selectively driven for each subpixel. In an example, FIG. 3 shows one transistor TFT provided at each of the subpixels SP (RSP, WSP, BSP, and GSP), but the subpixel may include two or more transistors as desired. A pixel circuit of each of the subpixels RSP, WSP, BSP, and GSP may include one or more switching transistors configured to control whether each of the subpixels SP (RSP, WSP, BSP, and GSP) is turned on or off and a driving transistor configured to supply driving current to the light emitting device ED.

In the light emitting display device, the first anode AND1, the second anode AND2, the third anode AND3, and the fourth anode AND4 are provided at the red, white, blue, and green subpixel RSP, WSP, BSP, and GSP, respectively. The first to fourth anodes AND1, AND2, AND3, and AND4 are spaced apart from each other, enabling the subpixels RSP, WSP, BSP, and GSP to be driven independently.

As shown in FIGS. 2 and 3, the light emitting device ED1 of each of the red subpixel RSP and the white subpixel WSP includes a first anode AND1 or a second anode AND2, an intermediate layer OS, and a cathode CAT. The light emitting device ED2 of each of the blue subpixel BSP and the green subpixel GSP includes a third anode AND3 or a fourth anode AND4, an intermediate layer OS, and a cathode CAT. The first and second anodes AND1 and AND2 have different characteristics from the third and fourth anodes AND3 and AND4 in terms of having a lower refractive index at the same wavelength and a lower surface resistance.

The intermediate layer OS includes a plurality of light emitting stacks, but may have the same configuration over the plurality of subpixels RSP, WSP, BSP, and GSP.

The light emitting device of the light emitting display device according to the present disclosure has a structure in which at least the intermediate layer 152 is commonly provided at each of the subpixels RSP, GSP, BSP, and WSP.

In an example, as shown in FIG. 4, the light emitting devices ED (ED1 and ED2) may include a plurality of light emitting stacks S1, S2, S3, and S4 between the anodes AND (AND1, AND2, AND3, and AND4) and the cathode CAT, and charge generation layers CGL1, CGL2, and CGL3 between the light emitting stacks S1, S2, S3, S4. Commonly, in the configuration of the light emitting device ED of each of the subpixels RSP, GSP, BSP, and WSP, the light emitting device may emit white light.

A red filter 109R, a blue filter 109B, and a green filter 109G provided in the red subpixel RSP, the blue subpixel BSP, and the green subpixel GSP, respectively, allow red light, blue light, and green light to be emitted therethrough.

The white subpixel WSP does not have a color filter and may directly emit white light emitted from the light emitting device ED through the substrate 100.

In an example, as shown in FIG. 4, a first light emitting stack S1 that emits red light, a second light emitting stack S2 that emits blue light, a third light emitting stack S3 that emits green light, and a fourth light emitting stack S4 that emits blue light may be sequentially stacked in the intermediate layer OS.

The light emitting stacks S1, S2, S3, and S4 may include light emitting layers REML, BEML1, GEML, and BEML2, first common layers CML11, CML12, CML13, and CML14 for hole transport may be provided under the light emitting layers REML, BEML1, GEML, and BEML2, and second common layers CML21, CML22, CML23, and CML24 for electron transport may be provided above the light emitting layers REML, BEML1, GEML, and BEML2. Each of the first common layers CML11, CML12, CML13, and CML14 may include a hole injection layer, a hole transport layer, and an electron blocking layer. Each of the second common layers CML21, CML22, CML23, and CML24 may include a hole blocking layer, an electron transport layer, and an electron injection layer.

That is, FIG. 4 shows an intermediate layer OS having a stacking arrangement of an R/B1/G/B2 stack of light emitting stacks in the direction from the anodes AND (AND1, AND2, AND3, and AND4) to the cathode CAT. Even if the intermediate layer OS and the cathode CAT of the light emitting device ED are included identically at each of the subpixels RSP, WSP, BSP, and GSP, the anode material with the first characteristics and the anode material with the second characteristics included in the light emitting device ED exhibit different luminance characteristics and different efficiency characteristics based on the viewing angle depending on the characteristic difference between the anode material with the first characteristics and the anode material with the second characteristics.

Color filters 109R, 109B, and 109 W between the light emitting device ED and the substrate 100 enable individual color expression different from white for each of the subpixels RSP, BSP, and GSP. The white subpixel WSP having no color filter emits white light through the light emitting device ED.

Specifically, as shown in FIG. 4, the intermediate layer OS of the light emitting device ED includes four light emitting stacks and three charge generation layers.

However, the light emitting device according to the embodiment of the present disclosure is not limited thereto. For example, when a plurality of light emitting stacks is arranged between first and second electrodes, the red light emitting stack, the green light emitting stack, and the first and second blue light emitting stacks may be sequentially disposed (R/G/B1/B2), the green light emitting stack, the red light emitting stack, and the first and second blue light emitting stacks may be sequentially disposed (G/R/B1/B2), the first blue light emitting stack, the red light emitting stack, the green light emitting stack, and the second blue light emitting stack may be sequentially disposed (B1/R/G/B2), or the light emitting stacks may be disposed in other different orders between the first and second electrodes, unlike the example shown in FIG. 5, in which the light emitting stacks are disposed by color.

Here, the two blue light emitting stacks are disposed in the light emitting device in order to compensate for efficiency of blue light lower than the other colors.

The light emitting device including the first to fourth light emitting stacks S1, S2, S3, and S4 may emit white light when more than a certain level of voltage is applied between the anodes AND (AND1, AND2, AND3, and AND4) and the cathode CAT.

The light emitting device ED of the light emitting display device according to the present disclosure is not limited to the example shown in FIG. 4. Unlike the example shown in FIG. 4, the intermediate layer OS of the light emitting device ED may have five or more light emitting stacks in addition to the four light emitting stacks.

The configuration disposed under the light emitting device ED will be described.

Each of a buffer layer 101, a gate insulating layer 103, an interlayer insulating layer 105, and a first protective layer 105 disposed on the substrate 100 may be made of an inorganic insulating layer. The inorganic insulating layer may be at least one of a silicon oxide layer, a silicon nitride layer, or a silicon oxynitride layer. Each of the buffer layer 101, the gate insulating layer 103, interlayer insulating layer 105, and the first protective layer 105 may include a single layer or multiple layers.

In an example, a transistor TFT may include a gate electrode 102, an active layer 104, and a source electrode 106a and a drain electrode 106b connected to both sides of the active layer 104. A channel protection layer configured to prevent direct connection between the source/drain electrodes 106a and 106b and the active layer 104 may be further provided above the region where a channel of the active layer 104 is located. The buffer layer 101 may be provided on the substrate 100, and the transistor TFT may be located on the buffer layer 101.

A shielding pattern may be further provided under the transistor TFT with the buffer layer 101 interposed therebetween. The shielding pattern prevents light from entering the active layer 104 from under the substrate 100, thereby stabilizing the off characteristics of the transistor.

The gate insulating layer 103 is provided between the gate electrode 102 and the active layer 104.

The active layer 104 may be made of, for example, any one of an oxide semiconductor, amorphous silicon, and polycrystalline silicon, or a combination of two or more thereof. For example, when the active layer 104 is made of an oxide semiconductor, the heating temperature required for forming a thin-film transistor may be lowered, which increases the freedom in using the substrate 100 and makes it advantageous for application to a flexible display device.

The gate electrode 102 is provided on the gate insulating layer 103, and the interlayer insulating layer 105 may further be provided between the gate electrode 102 and the source electrode 106a/the drain electrode 106b.

In addition, the drain electrode 106b of the transistor TFT may be connected to the anodes AND (AND1, AND2, AND3, and AND4) via a contact hole CT provided in first and second protective layers 107 and 108.

The first protective layer 107 is configured to protect the transistor TFT, and in an example, the color filters 109R, 109G, and 109B may be provided on the first protective layer 107.

The second protective layer 108 may be provided on the first protective layer 107 including the color filters 109R, 109G, and 109B.

As shown in FIG. 3, when the plurality of subpixels includes a red subpixel RSP, a white subpixel WSP, a blue subpixel BSP, and a green subpixel GSP, the red filter 109R, the green filter 109G, and the blue filter 109B are provided at the other subpixels RSP, GSP, and BSP, excluding the white subpixel WSP.

White light passing through the anodes AND (AND1, AND2, AND3, and AND4) may be transmitted by wavelength.

The anodes AND (AND1, AND2, AND3, and AND4) are formed on the surface of the second protective layer 108, excluding the contact hole CT, and are connected to any one of the drain electrode 106b and the source electrode 106a of the transistor TFT to receive an electrical signal from the transistor TFT.

Here, the substrate 100, the thin layer transistor TFT, the color filters 109R, 109G, and 109B, and the first and second protective layers 107 and 108 may constitute a thin layer transistor array substrate 1500.

The second protective layer 108 may include an organic insulating material.

For example, the organic insulating material may include at least one of an acrylic resin, a phenolic resin, a polyimide resin, an unsaturated polyester resin, a polyamide resin, benzocyclobutene, a polyphenylene resin, and a polyphenylene sulfide resin.

The light emitting device ED is formed on the thin-film transistor array substrate 1500 including the bank 119 that defines the light emitting portions REM, WEM, BEM, and GEM of the subpixels RSP, WSP, BSP, and GSP in an opening BH.

The light emitting device ED has a cathode CAT, which is a reflective electrode, opposite the transparent anodes AND (AND1, AND2, AND3, and AND4).

As shown in FIG. 4, the intermediate layer OS provided between the anodes AND (AND1, AND2, AND3, and AND4) and the cathode CAT includes a plurality of light emitting stacks S1, S2, S3, and S4 and first to third charge generation layers CGL1, CGL2, and CGL3.

The first to third charge generation layers CGL1, CGL2, and CGL3 include n-type charge generation layers NCGL1, NCGL2, and NCGL3 and p-type charge generation layers PCGL1, PCGL2, and PCGL3, respectively.

A shielding pattern 111 configured to prevent light entering through the substrate 100 from affecting the active layer 112 may be further provided under the transistor TFT. The shielding pattern 111 is preferably formed with an area equal to or greater than the area of the channel area of the active layer 112. In some cases, the shielding pattern 111 may be omitted.

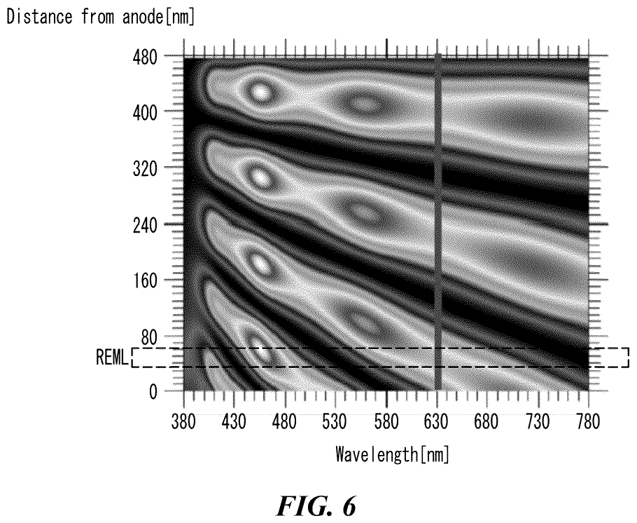

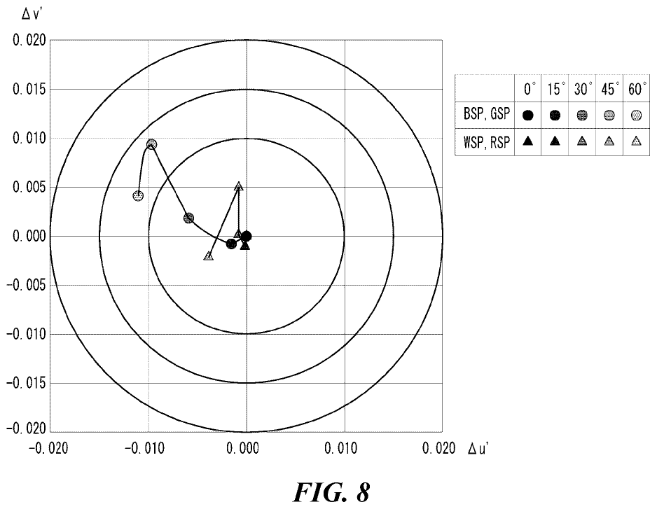

Hereinafter, the effects of the light emitting display device according to the embodiment of the present disclosure will be described with reference to Table 2 and FIGS. 6 and 8.

TABLE 2

| | | First anode | Second anode |
|---|---|---|---|
| | Anode | material | material |
| | Applied | WSP, RSP | GSP, BSP |
| | subpixel | | |
| | R | 16.8~18.4 | 16.5~17.7 |
| Efficiency | G | 50.3~52.8 | 53.2~55.9 |
| (Cd/A @ | B | 6.9~7.2 | 6.9~7.2 |
| full white) | W | 127.5~134.2 | 131.9~139.1 |
| Color | Rx | 0.692 (0.691~0.692) | 0.691 (0.691~0.691) |
| coordinates | Ry | 0.308 (0.308~0.309) | 0.309 (0.308~0.309) |
| | Gx | 0.241 (0.238~0.246) | 0.241 (0.238~0.246) |
| | Gy | 0.704 (0.699~0.706) | 0.706 (0.701~0.709) |
| | Bx | 0.149 (0.149~0.150) | 0.150 (0.149~0.151) |
| | By | 0.048 (0.047~0.049) | 0.048 (0.047~0.049) |
| White color | Wx | 0.300 (0.297~0.304) | 0.299 (0.296~0.301) |
| coordinates | Wy | 0.325 (0.322~0.329) | 0.329 (0.326~0.335) |

| | | |
|---|---|---|
| Color temperature (CCT) | 7255(6964~7515) | 7295(7095~7485) |
| Color viewing angle | 0.015(0.012~0.015) | 0.020(0.014~0.020) |
| (Max Δu′v′) | | |
| Voltage @100 mA/cm² | 17.9 (16.6~17.9) | 18.1 (16.8~18.1) |

As shown in Table 2, it can be seen that, when the anode material with the first characteristics presented in Table 1 is provided in each of the red subpixel RSP and the white subpixel WSP, the red efficiency is improved and the red color coordinates are improved.

In addition, when the anode material with the second characteristics is provided at each of the blue subpixel BSP and the green subpixel GSP during anode formation, the green efficiency is further improved compared to when the anode material with the first characteristics is provided at the blue or green subpixel and the blue efficiency is equal to or higher than that of the anode material with the first characteristics.

Furthermore, in panel operation, the white color coordinates, color temperature, color viewing angle characteristics, and driving voltage characteristics are significantly controlled by the characteristics of the white subpixel. When the anode material with the first characteristics shown in Table 1 is provided at each of the red subpixel RSP and the white subpixel WSP and the anode material with the second characteristics anode material is provided at each of the blue subpixel BSP and the green subpixel GSP, mass production is easy due to white color coordinate characteristics, and the maximum value of Au′v′ of the color viewing angle decreases, reducing color deviation when the viewing angle is changed. In addition, the driving voltage follows the driving voltage of the white subpixel, and the surface resistance of the second anode AND2 applied to the white subpixel decreases, thereby reducing the driving voltage.

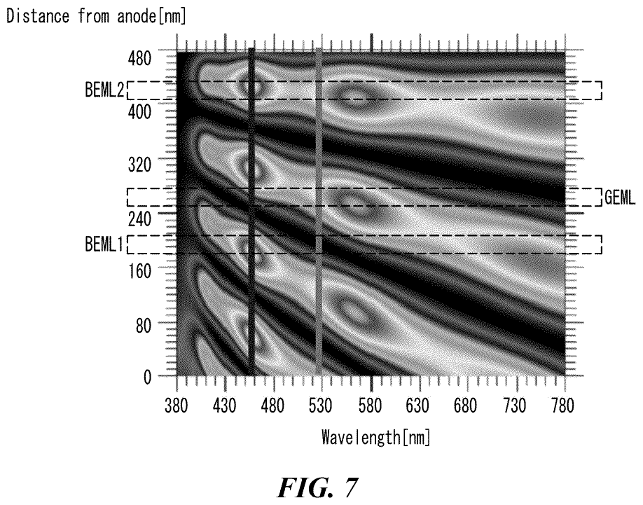

FIG. 6 is a contour map of the white subpixel and the red subpixel of the light emitting display device according to the embodiment of the present disclosure. FIG. 7 is a contour map of the blue subpixel and the green subpixel of the light emitting display device according to the embodiment of the present disclosure.

FIG. 6 is a contour map of a structure in which a light emitting device including an anode made of an anode material with first characteristics and four light emitting stacks of R/B1/G/B2 shown in FIG. 4 is applied.

FIG. 7 is a contour map of a structure in which a light emitting device including an anode made of an anode material with second characteristics and four light emitting stacks of R/B1/G/B2 shown in FIG. 4 is applied.

The contour map shows contour lines indicating the wavelength-specific peaks caused by resonance due to reflection and re-reflection of an organic material between the anode and the cathode with a predetermined distance therebetween.

Since, in the light emitting display device according to the embodiment of the present disclosure, an anode made of an anode material with first characteristics is provided at each of the red subpixel RSP and the white subpixel WSP, the position of a red light emitting layer REML of each of the red subpixel RSP and the white subpixel WSP may be determined according to the contour map of FIG. 6. Compared to the contour map of FIG. 7, the area with large light emission intensity at the red wavelength is more secured in the contour map of FIG. 6, whereby larger red light emission intensity may be secured when the red light emitting layer REML is disposed in the first light emitting stack S1 close to the anode.

Since, in the light emitting display device according to the embodiment of the present disclosure, an anode made of an anode material with second characteristics is provided at each of the blue subpixel BSP and the green subpixel GSP, each of the blue subpixel BSP and the green subpixel GSP follows the contour map of FIG. 7. The positions of the first and second blue light emitting layers BEML1 and BEML2 may be determined at the positions where the light emitting intensity is optimized in the second light emitting stack S2 and the fourth light emitting stack S4. In addition, the green light emitting layer GEML located in the third light emitting stack S3 may be disposed at a position where the light emitting intensity is relatively high.

FIG. 8 is a view showing the color viewing angle characteristics of the blue and green subpixels and the white and red subpixels for comparison.

In FIG. 8, the color viewing angle characteristics through the light emitting devices of the subpixels RSP, WSP, BSP, and GSP are compared.

The red subpixel and the white subpixel having the anode material with the first characteristics exhibit changes in CIEx (Δu′) and CIEy (Δv′) within a range of 0.005 when the viewing angle is varied to 0°, 15°, 30°, 45°, and 60°.

On the other hand, the blue subpixel and the green subpixel each having the anode material with the second characteristics exhibit that changes in CIEx (Δu′) and CIEy (Δv′) are large when the viewing angle is changed to 0°, 15°, 30°, 45°, and 60°, at a viewing angle of 45°, Δv′ changes significantly to a level of 0.010 compared to the front, and at a viewing angle of 60°, Δu′ changes to a level close to −0.012 compared to the front, indicating that the viewing angle changes significantly.

The viewing angle is evaluated by displaying white, and the color viewing angle characteristics may also be improved by reducing the viewing angle luminance change of the white subpixel.

A light emitting display device according to one embodiment of the present disclosure may comprise a first anode at a red subpixel, a second anode at a white subpixel, a third anode at a blue subpixel, and a fourth anode at a green subpixel, an intermediate layer on the first anode, the second anode, the third anode, and the fourth anode, the intermediate layer comprising four or more stacks and a charge generation layer between the stacks and a cathode on the intermediate layer. Each of the first anode and the second anode may have a lower refractive index than each of the third anode and the fourth anode for light of the same wavelength.

In a light emitting display device according to one embodiment of the present disclosure, each of the first anode and the second anode may have a lower surface resistance than each of the third anode and the fourth anode.

In a light emitting display device according to one embodiment of the present disclosure, the first anode, the second anode, the third anode, and the fourth anode may have the same thickness.

In a light emitting display device according to one embodiment of the present disclosure, each of the first anode, the second anode, the third anode, and the fourth anode may have a thickness of 450 Å to 650 Å.

In a light emitting display device according to one embodiment of the present disclosure, the intermediate layer which includes a first light emitting stack comprising a red light emitting layer, a first charge generation layer, a second light emitting stack comprising a first blue light emitting layer, a second charge generation layer, a third light emitting stack comprising a green light emitting layer, a third charge generation layer and a fourth light emitting stack comprising a second blue light emitting layer may be provided between the first to fourth anodes and the cathode.

In a light emitting display device according to one embodiment of the present disclosure, the red light emitting layer, the first blue light emitting layer, the green light emitting layer, and the second blue light emitting layer may be sequentially disposed between the first to fourth anodes and the cathode.

In a light emitting display device according to one embodiment of the present disclosure, the first anode and the second anode may have the same refractive index, and the third anode and the fourth anode may have the same refractive index.

In a light emitting display device according to one embodiment of the present disclosure, each of the first anode and the second anode may have a refractive index of 1.65 to 1.80 for a red wavelength, a refractive index of 1.81 to 1.89 for a green wavelength, and a refractive index of 1.90 to 1.97 for a blue wavelength.

In a light emitting display device according to one embodiment of the present disclosure, a refractive index difference between the third and fourth anodes and the first and second anodes may decrease as the wavelength of the light becomes shorter.

In a light emitting display device according to one embodiment of the present disclosure, the first anode and the second anode may have the same first surface resistance, and each of the third anode and the fourth anode may have a second surface resistance greater than the first surface resistance.

In a light emitting display device according to one embodiment of the present disclosure, the red subpixel and the white subpixel may abut each other without a gap in a plan view, and the blue subpixel and the green subpixel may abut each other without a gap in a plan view.

In a light emitting display device according to one embodiment of the present disclosure, each of the first anode, the second anode, the third anode, and the fourth anode may comprise one of indium tin oxide (ITO) and indium zinc oxide (IZO).

In a light emitting display device according to one embodiment of the present disclosure, each of the first anode, the second anode, the third anode, and the fourth anode may comprise a transparent metal oxide. An oxygen content of each of the first anode and the second anode may be less than an oxygen content of each of the third anode and the fourth anode.

In a light emitting display device according to one embodiment of the present disclosure, each of the first anode, the second anode, the third anode, and the fourth anode may comprise a transparent metal oxide. A crystal size in the transparent metal oxide of each of the first anode and the second anode may be greater than a crystal size in the transparent metal oxide of each of the third anode and the fourth anode.

A light emitting display device according to one embodiment of the present disclosure may further comprise a substrate on which, the red subpixel, the white subpixel, the blue subpixel, and the green subpixel are disposed, a transistor connected to each of the first to fourth anodes between the substrate and the first to fourth anodes, a red filter between the substrate and the first anode, a blue filter between the substrate and the third anode and a green filter between the substrate and the fourth anode.

In the light emitting display device according to the present disclosure, a light emitting device including four or more light emitting stacks may be disposed at each subpixel, each of red and green subpixels includes an anode material having first characteristics of a relatively low refractive index, and each of blue and green subpixels includes an anode material having second characteristics of a relatively high refractive index, such that the anode refractive indices of the subpixels are different from each other, thereby maximizing the efficiency of each subpixel, reducing the color viewing angle characteristics change due to the viewing angle change, and improving the image quality characteristics of the light emitting display device.

In addition, the surface resistance characteristics of a transparent metal oxide included in the anode may be adjusted for each subpixel, thereby effectively reducing the driving voltage required to drive the light emitting device.

Accordingly, the driving power of the light emitting display device including the light emitting device may be reduced.

In the light emitting display device according to the present disclosure, a scattering pattern that is easy to pattern over a large area between the light emitting device and the substrate is provided at each of predetermined subpixels, and leakage current may be prevented by varying a structure in which the scattering pattern and a color filter are stacked between adjacent subpixels to increase the path length of the intermediate layer between adjacent subpixels, thereby preventing leakage between adjacent subpixels. Therefore, continuous applicability is possible due to improved luminance viewing angle and prevention of light leakage, whereby ESG (environmental/social/governance) goals may be achieved.

As is apparent from the above description, in a light emitting display device according to the present disclosure, anodes having the same thickness but different optical and electrical characteristics may be provided at subpixels so as to correspond to subpixel characteristics.

In the light emitting display device according to the embodiment of the present disclosure, each of a red subpixel and a white subpixel includes an anode having a small refractive index and small surface resistance, thereby improving the efficiency of the red subpixel and stabilizing the color coordinate characteristics of the white subpixel. In addition, the surface resistance of the white subpixel may be reduced to reduce the driving voltage.

In the light emitting display device, white display and white color coordinates are determined by the characteristics of the white subpixel. In the light emitting display device according to the embodiment of the present disclosure, the color viewing angle characteristics of the light emitting display device may also be improved by adjusting the anode of the white subpixel.

In the light emitting display device according to the present disclosure, the thickness of an anode in a light emitting display device including four or more light emitting stacks may be reduced, thereby reducing the thickness of an organic material required for a light emitting device and thus reducing the driving voltage.

In the embodiment of the present disclosure, image quality may be improved by preventing color deviation characteristics due to viewing angle changes in a light emitting display device with a tandem structure.

In the light emitting display device according to the present disclosure, the thicknesses of the anodes of the subpixels are similar to each other, but different layer formation conditions are applied to the anodes, thereby changing the optical and electrical characteristics of the light emitting device by the difference in the anode material for each subpixel. As a result, environmental pollution is prevented by not adding additional materials, and benefits such as reduced driving voltage, stabilization of white color coordinates, improved red efficiency, and improved color viewing angle characteristics are achieved. In the light emitting display device, therefore, continuous applicability is possible, whereby ESG (environmental/social/governance) goals may be achieved.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate including a red subpixel, a white subpixel, a blue subpixel, and a green subpixel;
a first anode at the red subpixel, a second anode at the white subpixel, a third anode at the blue subpixel, and a fourth anode at the green subpixel;
an intermediate layer on the first anode, the second anode, the third anode, and the fourth anode, the intermediate layer comprising four or more stacks and a charge generation layer between the stacks; and
a cathode on the intermediate layer,
wherein each of the first anode and the second anode has a lower refractive index than each of the third anode and the fourth anode for light of the same wavelength.

2. The light emitting display device according to claim 1, wherein each of the first anode and the second anode have a lower surface resistance than each of the third anode and the fourth anode.

3. The light emitting display device according to claim 1, wherein the first anode, the second anode, the third anode, and the fourth anode have the same thickness.

4. The light emitting display device according to claim 1, wherein each of the first anode, the second anode, the third anode, and the fourth anode has a thickness of 450 Å to 650 Å.

5. The light emitting display device according to claim 1, wherein the four or more stacks include a first light emitting stack comprising a red light emitting layer, a second light emitting stack comprising a first blue light emitting layer, a third light emitting stack comprising a green light emitting layer, and a fourth light emitting stack comprising a second blue light emitting layer, and the four or more stacks are provided between the first to fourth anodes and the cathode, and
wherein the charge generation layer is one of a plurality of charge generation layers including a first charge generation layer, a second charge generation layer, a third charge generation layer, and a fourth charge generation layer.

6. The light emitting display device according to claim 5, wherein the red light emitting layer, the first blue light emitting layer, the green light emitting layer, and the second blue light emitting layer are sequentially disposed between the first to fourth anodes and the cathode.

7. The light emitting display device according to claim 1, wherein:
the first anode and the second anode have the same refractive index, and
the third anode and the fourth anode have the same refractive index.

8. The light emitting display device according to claim 1, wherein each of the first anode and the second anode has a refractive index of 1.65 to 1.80 for a red wavelength, a refractive index of 1.81 to 1.89 for a green wavelength, and a refractive index of 1.90 to 1.97 for a blue wavelength.

9. The light emitting display device according to claim 8, wherein a refractive index difference between the third and fourth anodes and the first and second anodes decreases as the wavelength becomes shorter.

10. The light emitting display device according to claim 1, wherein:
the first anode and the second anode have the same first surface resistance, and
each of the third anode and the fourth anode has a second surface resistance greater than the first surface resistance.

11. The light emitting display device according to claim 1, wherein:
the red subpixel and the white subpixel abut each other without a gap in a plan view, and
the blue subpixel and the green subpixel abut each other without a gap in a plan view.

12. The light emitting display device according to claim 1, wherein each of the first anode, the second anode, the third anode, and the fourth anode comprises one of indium tin oxide (ITO) and indium zinc oxide (IZO).

13. The light emitting display device according to claim 3, wherein:
each of the first anode, the second anode, the third anode, and the fourth anode comprises a transparent metal oxide, and
an oxygen content of each of the first anode and the second anode is less than an oxygen content of each of the third anode and the fourth anode.

14. The light emitting display device according to claim 3, wherein:
each of the first anode, the second anode, the third anode, and the fourth anode comprises a transparent metal oxide, and
a crystal size in the transparent metal oxide of each of the first anode and the second anode is greater than a crystal size in the transparent metal oxide of each of the third anode and the fourth anode.

15. The light emitting display device according to claim 1, further comprising:
a transistor connected to each of the first to fourth anodes between the substrate and the first to fourth anodes;
a red filter between the substrate and the first anode;
a blue filter between the substrate and the third anode; and
a green filter between the substrate and the fourth anode.
